(19) United States
(12) Patent Application Publication
(10) Pub. No.: US 2010/0037624 A1
(43) Pub. Date: Feb. 18, 2010

(54) ELECTROCALORIC REFRIGERATOR AND MULTILAYER PYROELECTRIC ENERGY GENERATOR

(76) Inventors: Richard I. EPSTEIN, Santa Fe, NM (US); Kevin J. Malloy, Albuqerque, NM (US)

Correspondence Address: MH2 TECHNOLOGY LAW GROUP, LLP, 1951 KIDWELL DRIVE, SUITE 550, TYSONS CORNER, VA, 22182, US

(21) Appl. No.: 12/354,436

(22) Filed: Jan. 15, 2009

Related U.S. Application Data
(60) Provisional application No. 61/021,183, filed on Jan. 15, 2008.
(60) Provisional application No. 61/021,177, filed on Jan. 15, 2008.

(51) Int. Cl. F25B 21/00; B23P 15/00; H05K 7/20; F28F 7/00; H02N 11/00

(52) U.S. Cl. 62/3.1; 29/890.035; 361/688; 165/276; 322/2 R

(57) ABSTRACT

In accordance with the invention, there are electrocaloric devices, pyroelectric devices and methods of forming them. A device which can be a pyroelectric energy generator or an electrocaloric cooling device, can include a first reservoir at a first temperature and a second reservoir at a second temperature, wherein the second temperature is higher than the first temperature. The device can also include a plurality of liquid crystal thermal switches disposed between the first reservoir and the second reservoir and one or more active layers disposed between the first reservoir and the second reservoir, such that each of the one or more active layers is sandwiched between two liquid crystal thermal switches. The device can further include one or more power supplies to apply voltage to the plurality of liquid crystal thermal switches and the one or more the active layers.

### RELATED APPLICATIONS

This application claims priority from U.S. Provisional Patent Application Ser. Nos. 61/021,177 and 61/021,183, filed Jan. 15, 2008, which are hereby incorporated by reference in their entirety.

### GOVERNMENT RIGHTS

This invention was made with government support under Contract No. FA9550-04-1-0356 awarded by the Air Force Office of Scientific Research. The government has certain rights in the invention.

### FIELD OF THE INVENTION

The subject matter of this invention relates refrigeration and power generators. More particularly, the subject matter of this invention relates to devices and methods of making single-layer and multilayer electrocaloric refrigerators and pyroelectric energy generators.

### BACKGROUND OF THE INVENTION

Currently, the great majority of devices for near room-temperature refrigeration and air conditioning are based on vapor compression technology. In some small niche applications, solid state thermoelectric devices are used. While the solid state thermoelectric devices are much less efficient than vapor compression devices, they are compact and without moving parts or fluids. Both of these technologies are mature and are unlikely to improve much in the foreseeable future. There have been small efforts to develop electrocaloric or magnetocaloric refrigerators, but practical and economic obstacles have prevented their use in practical coolers. Early attempts by Radebaugh et al. ( Radebaugh, R; Lawless, W N; Siegwarth, J D; Morrow, A J Cryogenics, Vol. 19, No. 4, pp. 187-208,1979) and Hadni ( Hadni, A J. PHYS. E: SCI. INSTR., Vol. 14, No. 11, pp. 1233-1240, 1981)to develop a cryogenic electrocaloric refrigerator were unsuccessful because the electric fields needed for the required temperature swings were larger than the breakdown fields.

Furthermore, most of the effort in directly extracting electrical energy from heat utilizes some type of thermoelectric material. The thermoelectric approach has been vigorously pursued for decades with modest, incremental success. However, no major breakthroughs have occurred. Pyroelectric energy conversion has been examined for many years, but little progress has been made in developing practical systems. The most efficient systems that have been investigated use the “Olsen cycle”, which involves regenerators and requires moving parts and fluid flow, as described by Lang & Muensit, Appl. Phys. A, 85, 125-134 (2005). Additionally, because this conventional pyroelectric approach uses a single material to span the entire temperature range, the pyroelectric coefficient is well below its maximum value over much of this range.

Hence, there is a need for a new refrigeration device which is more efficient, versatile, and economical than conventional vapor compression refrigerators and a new pyroelectric approach to extract power.

### SUMMARY OF THE INVENTION

In accordance with various embodiments, there is a device including a first reservoir at a first temperature and a second reservoir at a second temperature, wherein the second temperature is higher than the first temperature. The device can also include a plurality of liquid crystal thermal switches disposed between the first reservoir and the second reservoir and one or more active layers disposed between the first reservoir and the second reservoir, such that each of the one or more active layers is sandwiched between two liquid crystal thermal switches. The device can further include one or more power supplies to apply voltage to the plurality of liquid crystal thermal switches and the one or more the active layers.

According to various embodiments, there is a method of forming a device. The method can include providing a first reservoir at a first temperature and providing a second reservoir at a second temperature, wherein the second. temperature is higher than the first temperature. The method can also include forming one or more multilayer stacks of alternating active layers and liquid crystal thermal switches between the first reservoir and the second reservoir, such that each active layer is sandwiched between two liquid crystal thermal switches. The method can further include providing one or more power supplies to apply voltage to the plurality of liquid crystal thermal switches and the one or more active layers.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

FIG. 1A schematically illustrates an exemplary device, according to various embodiments of the present teachings.

FIG. 1B schematically illustrates an exemplary active layer of the device shown in FIG. 1A, according to various embodiments of the present teachings.

FIGS. 2A-2C show schematic illustration of an exemplary thermal switch, in accordance with various embodiments.

FIG. 3 shows a schematic illustration of an exemplary device with a single active layer sandwiched between two thermal switches, in accordance with various embodiments.

FIG. 4 shows a Carnot cycle in the temperature-entropy plane for an exemplary electrocaloric cooling device as shown in FIG. 3, in accordance with the present teachings.

FIG. 5 shows a Carnot cycle in the displacement-electric field plane for the exemplary electrocaloric cooling device shown in FIG. 3, in accordance with the present teachings.

FIG. 6A shows heat flow during the warm isothermal phase of the Carnot cycle shown in FIG. 4 for the exemplary electrocaloric cooling device shown in FIG. 3, according to various embodiments of the present teachings.

FIG. 6B shows heat flow during the cool isothermal phase of the Carnot cycle shown in FIG. 4 for the exemplary electrocaloric cooling device shown in FIG. 3, according to various embodiments of the present teachings.

FIG. 7 shows operation of an exemplary multilayer electrocaloric cooling device, in accordance with various embodiments of the present teachings.

FIG. 8 shows a Carnot cycle in the temperature-entropy plane for an exemplary pyroelectric energy generator as shown in FIG. 3, in accordance with the present teachings.

FIG. 9 shows a Carnot cycle in the displacement-electric field plane for an exemplary pyroelectric energy generator as shown in FIG. 3, in accordance with the present teachings.

FIG. 10A shows heat flow during the warm isothermal phase of the Carnot cycle shown in FIG. 8 for the exemplary pyroelectric energy generator shown in FIG. 3, according to various embodiments of the present teachings.

FIG. 10B shows heat flow during the cool isothermal phase of the Carnot cycle shown in FIG. 8 for the exemplary pyroelectric energy generator shown in FIG. 3, according to various embodiments of the present teachings.

FIG. 11 shows operation of an exemplary multilayer pyroelectric generator, in accordance with various embodiments of the present teachings.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

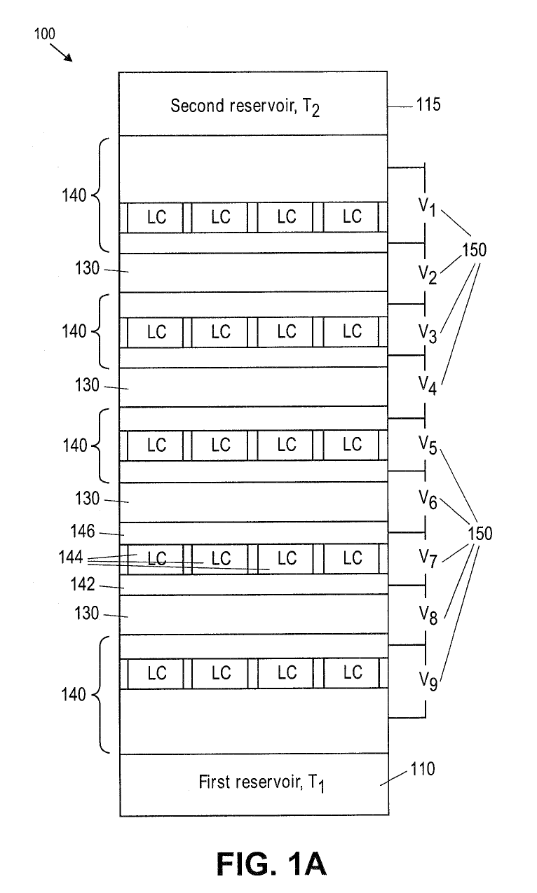

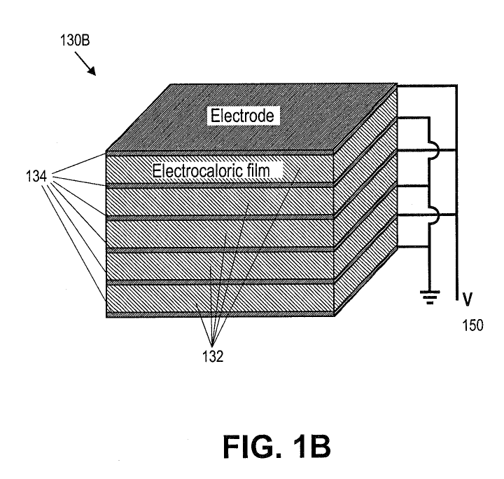

FIG. 1A schematically illustrates an exemplary device 100, according to various embodiments of the present teachings. The device 100 can include a first reservoir 110 at a first temperature T₁ and a second reservoir 115 at a second temperature T₂, wherein the first temperature T₁ is lower than the second temperature T₂. Depending upon the application in which the device 100 is used, the first reservoir 110 and the second reservoir 115 can be, but is not limited to, one or more of ambient air, a storage unit of a refrigerator, one or more electronic components of an electronic device, an electronic device, a furnace, a radiator of an automobile, an exhaust system of an automobile, a human body, and any other suitable heat sink. The device 100 can also include a plurality of liquid crystal thermal switches 140 disposed between the first reservoir 110 and the second reservoir 115. The device 100 can further include one or more active layers 130 disposed between the first reservoir 110 and the second reservoir 115, such that each of the one or more active layers 130 can be sandwiched between two liquid crystal thermal switches 140. FIG. 1B schematically illustrates another embodiment, wherein each of the one or more active layers 130 can further include a stack of alternating thin active layers 132 and electrode layers 134, such that each of the thin active layer 132 is disposed between two electrode layers 134. The device 100 can further include one or more power supplies 150 to apply voltage to one or more of the liquid crystal thermal switches 140 and the active layers 130.

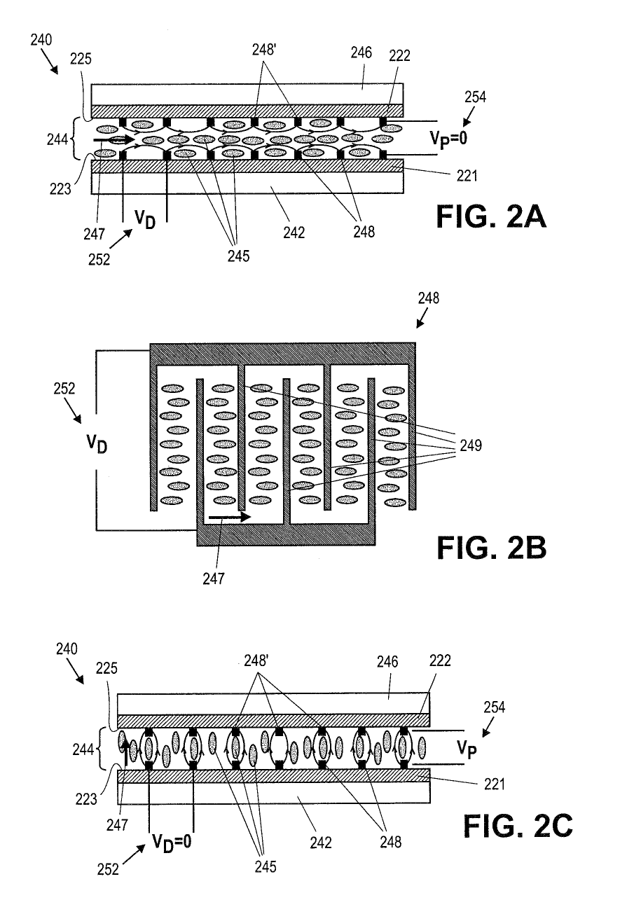

In various embodiments, each of the plurality of liquid crystal thermal switches 140 can include a thin layer 144 of liquid crystal sandwiched between two metal layers 142, 146, as shown in FIG. 1A. FIGS. 2A-2C show another exemplary thermal switch 240 in accordance with various embodiments of the present teachings. The thermal switch 240 can include a first metal layer 244 and a first insulating layer 221 disposed over the first metal layer 246, wherein the first insulating layer 221 can include one or more pairs of first interdigitated electrodes 248 on a first surface 223. In various embodiments, each of the one or more pairs of first interdigitated electrodes 248 can include a plurality of first electrodes 249, as shown in FIG. 2B. The thermal switch 240 can also include a second insulating substrate 222 including a second pair of interdigitated electrodes 248 on a second surface 225. Each of the one or more pairs of second interdigitated electrodes 248 can have a structure as shown in FIG. 2B. The thermal switch 240 can further include a thin layer 244 of liquid crystal 245 disposed between the first surface 223 of the first insulating substrate 221 and the second surface 225 of the second insulating substrate 222, wherein the liquid crystal 245 can have anisotropic thermal conductivity. As used herein, the term “anisotropic thermal conductivity” means different thermal conductivities in the direction perpendicular and parallel to the director 247 of the liquid crystal 245. The ratio of these thermal conductivities has been measured and can be larger than about 3. The thermal switch 240 can also include a second metal layer 246 disposed over the second insulating layer 222, as shown in FIG. 2A. FIG. 2A shows the open state where the thermal conductivity across the thin layer 244 of the liquid crystal 245 is low. FIG. 2C shows the closed state, where the thermal conductivity across the thin layer 244 of liquid crystal 245 is high.

Exemplary liquid crystal can include, but are not limited to ZL1-2806 and MLC-2011 (Merck, Japan). In some embodiments, the thin layer 144 of liquid crystal can include a plurality of carbon nanotubes. While not intending to be bound by any specific theory, it is believed that the addition of carbon nanotubes can further enhance the anisotropy of the thermal conductivity of the thin layer 130 of liquid crystal 132.

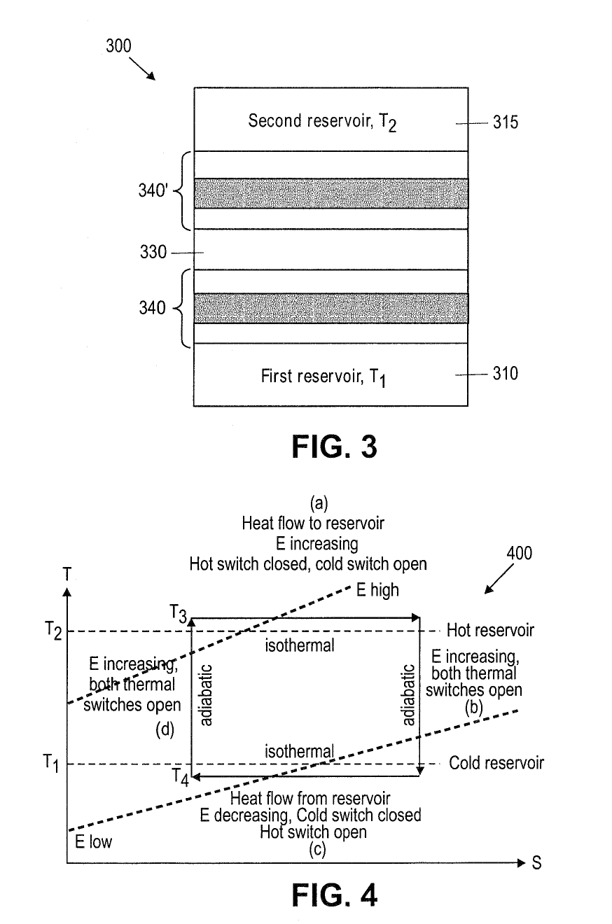

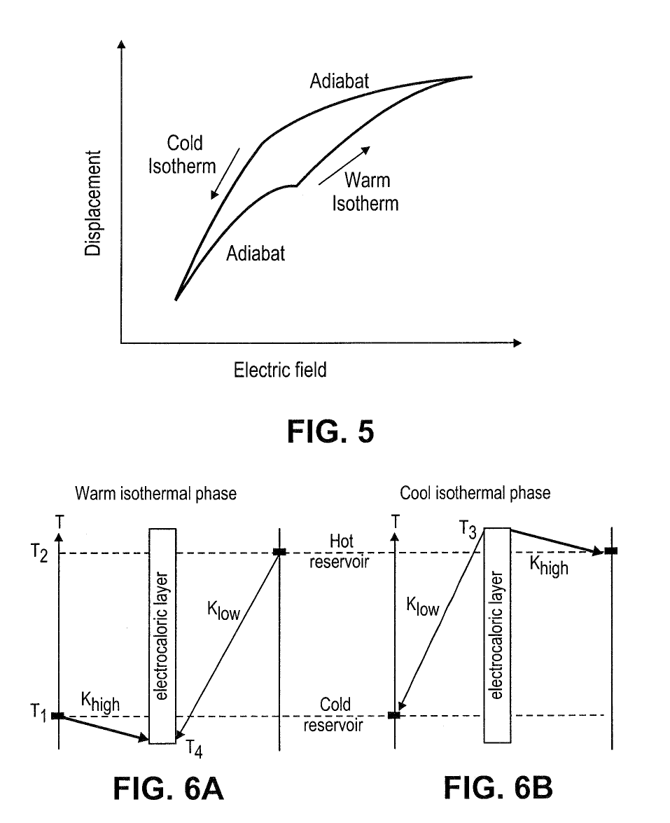

In various embodiments, each of the one or more active layers 130 and the liquid crystal thermal switches 140, 240 can have a thickness from about 10 μm to about 100 μm. In certain embodiments, as shown in FIG. 1B, each of the thin active layers 132 can have a thickness from about 0.01 μm to about 5 μm and in some cases from about 0.1 μm to about 1 μm. In some embodiments, the device 100 can have tens of layers, depending upon the temperature difference between the first and the second reservoirs 110, 115. In other embodiments, the device 100 can have a thickness on the order of millimeters. FIG. 3 shows another embodiment, where the device 300 can include only one active layer 330 between the first reservoir 310 and the second reservoir 315, such that the active layer 330 can be sandwiched between the two liquid crystal thermal switches 340, 340′.

In certain embodiments, each of the one or more active layers 130 can include an electrocaloric layer and the device 100 can be an electrocaloric cooling device. Exemplary electrocaloric materials include, but are not limited to, PbZrₓTi₍₁₋ₓ₎O₃ (PZT), poly(vinylidene fluoride) (PVDF), poly(vinylidene fluoride-trifluoroethylene) [P(VDF-TrFE)], and ferroelectric liquid crystals. The principle physical mechanism in the electrocaloric cooling device 100 in accordance with the present teachings is the electrocaloric effect in which application of an electrical potential across an electrocaloric material changes its temperature. The exemplary electrocaloric. cooling device 100 overcomes previous disadvantages by making use of thin film technologies and by utilizing a thin film thermal switch. Since, heat flow is very rapid in thin films, effective refrigeration can be achieved through rapid voltage cycling of the electrocaloric material and through rapid operation of the heat switch, allowing significant fractions of Carnot efficiency with less than perfect materials. Larger temperature drops can be achieved by stacking several structures.

In various embodiments, there can be a food storage unit including the electrocaloric cooling device 100. In other embodiments, there can be an air conditioning unit including the electrocaloric cooling device 100. The air conditioning unit can be used in, for example, buildings and automobiles. In some other embodiments, there can be an electronic device including the electrocaloric cooling device 100 for cooling individual electronic components. In various embodiments, the electrocaloric cooling device 100 can be well suited for portable applications because of its compactness and ruggedness.

According to various embodiments, there is a method of driving heat flow from the first reservoir 110, 310 to the second reservoir 115, 315 in the electrocaloric cooling device 100, 300, using the Carnot cycle 400, shown in FIG. 4. For simplicity, an electrocaloric cooling device 300 including a single stack of electrocaloric layer 330 disposed between the first thermal switch 340 and the second thermal switch 340′, is shown in FIG. 3 and will be used for discussion of the method of operation. The Carnot cycle 400 shown in FIG. 4 is in the temperature-entropy plane, while FIG; 5 shows a Carnot cycle in the displacement-electric field plane. In various embodiments, the method of driving heat flow from the first reservoir 110, 310 to the second reservoir 115, 315 in the electrocaloric cooling device 100, 300, using the Carnot cycle 400 can include a first isothermal step (a) of closing the second liquid crystal thermal switch 340′ adjacent to the second reservoir 315 at a temperature T₂, opening the first liquid crystal thermal switch 340 on the other side of the electrocaloric layer 330 and adjacent to the first reservoir 310 at a temperature T₁ to transfer heat from the electrocaloric layer 330 at a temperature T₃ to the second reservoir at the temperature T₂, wherein T₃ is greater than T₂ and T₂ is greater than T₁. The isothermal step (a) can also include keeping the temperature of the electrocaloric layer 330 constant at T₃ by increasing the electric field across the electrocaloric layer 330. The Carnot cycle 400 can further include the adiabatic step (b) of opening both the first and the second liquid crystal thermal switches 340, 340′ and changing the temperature of the electrocaloric layer 330 from T₃ to T₄ (T₄ being less than T₁) by decreasing the electric field across the electrocaloric layer 330. The third step (c) of the Carnot cycle 400 can include closing the first liquid crystal thermal switch 340 adjacent to the first reservoir 310 at the temperature T₁ and opening the second liquid crystal thermal switch adjacent to the second reservoir 315 at a temperature T₂, to extract heat from the first reservoir 310 at the temperature T₁ to the electrocaloric layer 330 at T₄ because T₁>T₄. The isothermal step can also include keeping the temperature of the electrocaloric layer 330 constant at T₄ by decreasing the electric field across the electrocaloric layer 330. The Carnot cycle 400 can also include another adiabatic step (d) of opening both the first and the second liquid crystal thermal switches 340, 340′ and increasing the temperature of the electrocaloric layer from T₄ to T₃ by increasing the electric field across the electrocaloric layer 330. The steps a-d, can be repeated, as desired, across each stack of alternating electrocaloric layers 130, 330 and liquid crystal thermal switches 140, 340, 340′ of the multilayer stack of the electrocaloric cooling device 100, 300. The Carnot cycle 400 can be effectively used with the multilayer stack of the electrocaloric cooling device 100 because the temperature spanned by each layer of the electrocaloric cooling device 100 can be less than about 10° C. The four steps of the Carnot cycle 400 shown in FIG. 4 can be repeated across each stack of alternating electrocaloric layers 130 and liquid crystal thermal switches 140 of the multilayer stack. As the voltage across each electrocaloric layer 130 is changed, the electrocaloric layer 130 heats or cools from its average value. By opening and closing the liquid crystal thermal switches at the appropriate time, the heat can be forced to flow from the cold reservoir at T₁ to the warm reservoir at T₂.

FIGS. 6A and 6B illustrate the heat flow in a single electrocaloric layer 330 during the warm and cool isothermal phases of the Carnot cycle shown in FIG. 4. The relative thickness of the arrow indicates the magnitude of the heat flow through liquid crystal thermal switches 340, 340′. In the “closed” state, the liquid crystal thermal switches 340, 340′ can have high thermal conductivity Khigh, and in the open state they can have low thermal conductivity K_{low}. In various embodiments, the ratio K_{high}/K_{low} can be greater that 3. The larger the. ratio K_{high}/K_{low}, the lower the entropy generating heat leakage through the “open” liquid crystal thermal switches 340, 340′ and the greater the efficiency with which the electrocaloric refrigerator 300 can extract heat from the cold reservoir 310.

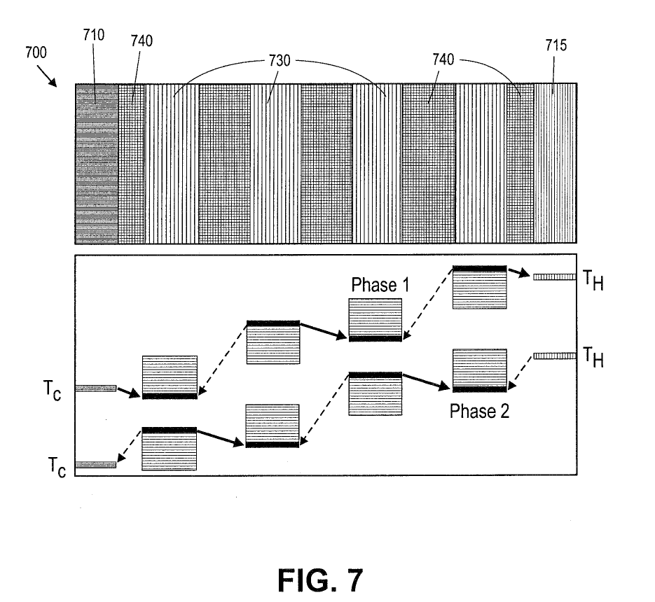

FIG. 7 illustrates operation of an exemplary multilayer electrocaloric cooling device 700, in accordance with various embodiments of the present teachings. To effectively use a stack of electrocaloric layers 730 in a heat engine such as, electrocaloric cooling device 700, the thermal connections between the electrocaloric layers 730 has to be opened and closed appropriately as the electrocaloric layers 730 are heated or cooled. The multilayer electrocaloric cooling device 700 can operate in a “bucket brigade” mode, rhythmically passing heat between adjacent electrocaloric layers 730. Thermal switches 740 on both sides of each of the electrocaloric layers 730 can control the heat flow. The top panel in FIG. 7 is a schematic of a thin-film electrocaloric cooling device 700 with four electrocaloric layers 730. The electrocaloric layers 730 can be connected to the hot and cold ends of the device 700 and to each other by thermal switches 740. The bottom panel shows the temperature profiles of the device 700 during two phases of operation when it is functioning as a refrigerator. During Phase 1 for the electrocaloric cooling device 700, the voltages across the electrocaloric layers 730 can be adjusted so that the first and third layers are cool relative to their average temperatures and the second and fourth are relatively warm. The thermal switches 740 can be adjusted so that the net heat flows are to the right from the cold reservoir 710 to the first electrocaloric layer, from the second layer to the third, and from the fourth layer to the hot reservoir 715. During the Phase 2, the voltages are adjusted such that electrocaloric layers 730 one and three are relatively warm and the electrocaloric layers 730 two and four are cooler. The thermal switches 740 are reversed so that the heat continues to flow towards the right (from electrocaloric layer 730 one to two and from electrocaloric layer 730 three to four). The shaded regions show the temperature range through which the electrocaloric material shifts between Phases 1 and 2.

Referring back to FIG. 4, this figure shows the thermodynamic cycle of a single layer of elbctrocaloric material of an electrocaloric cooling device in the temperature entropy plane. Two dashed curves of constant electric field are shown to indicate how the applied electric field changes around the cycle. Each electrocaloric layer 130, 330 730 undergoes a Carnot cycle. A changing electric field drives the vertical, adiabatic legs (b) and (d) of the cycle. A combination of heat flows and changing electric field maintains constant temperature in the horizontal isothermal legs (a) and (c). The efficiency of an actual thin-film heat engine/electrocaloric cooling device is lower than the Carnot value because of entropy generation from heat flows though the thermal switches and because of hysteresis in the electrocaloric material.

Furthermore, if the electrocaloric layer 130, 330, 730 comprises a multilayer structure 130B shown in FIG. 1B, wherein many sub-micron layers 132 can be separated by electrodes 134, the diffusion time can be made long relative to the response time of the thermal switches and large electric fields can be produced with low voltages.

The electrocaloric cooling devices 100 according to the present teachings can be thin, efficient devices that can function in a large array of novel situations. Furthermore, the materials used in the electrocaloric refrigerators can be relatively inexpensive and the growth techniques are simple and are well established in the prior art; these devices can be economically produced in large volumes and may prove to be more economical than vapor compression devices. The efficiency of the electrocaloric cooling devices can exceed those of vapor compression devices, depending on the performance of the liquid crystal thermal switches.

Referring back to the device 100, shown in FIG. 1, each of the one or more active layers 130 can include a pyroelectric layer and the device 100 can be a pyroelectric energy generator. Exemplary pyroelectric materials include, but are not limited to, PbZrₓTi₍₁₋ₓ)O₃ (PZT), poly(vinylidene fluoride) (PVDF), poly(vinylidene fluoride-trifluoroethylene) [P(VDF-TrFE)], and ferroelectric liquid crystals. The principle physical mechanism in the exemplary pyroelectric energy generator 100 in accordance with the present teachings is the pyroelectric effect in which a change in temperature of the pyroelectric material results in a generation of an electrical potential. The pyroelectric effect is opposite of the elecetrocaloric effect, where an applied voltage can reversibly change the temperature of the pyroelectriclelectrocaloric material. The exemplary pyroelectric energy generator 100 can use stacks of thin films of pyroelectric material 130 separated by liquid-crystal thermal switches 140 to generate electric energy from the heat flow from a hot medium 115 to a cool one 110. As the liquid-crystal thermal switches 140 open and close, heat flows into and out of each thin layer 130 of pyroelectric material. By appropriately adjusting the phase and amplitude of the voltages across each layer, electric power can be efficiently extracted through Carnot cycle.

In various embodiments, there can be an automobile including the pyroelectric energy generator 100 for extracting electrical energy from a surface that can be at a temperature different from its surrounding environment. In some embodiments, the surface can be a radiator. In other embodiments, the surface can be an exhaust system. In some embodiments, there is a furnace including the pyroelectric energy generator 100 for extracting electrical energy from its surface that is at a temperature different from its surrounding environment. In other embodiments, either the first reservoir 110 or the second reservoir 120 of the exemplary pyroelectric energy generator 100 can include a human body.

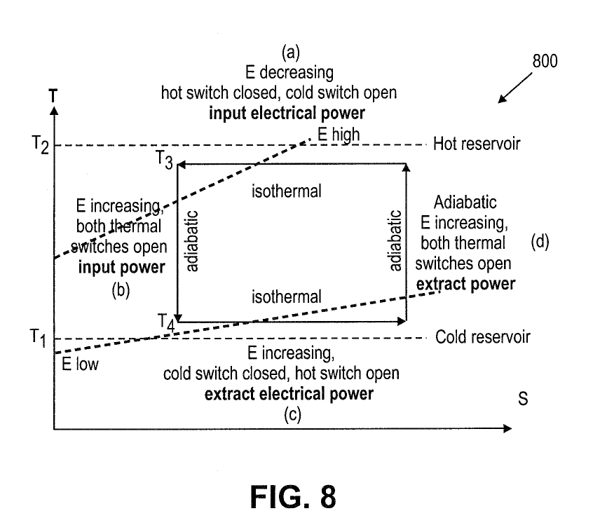

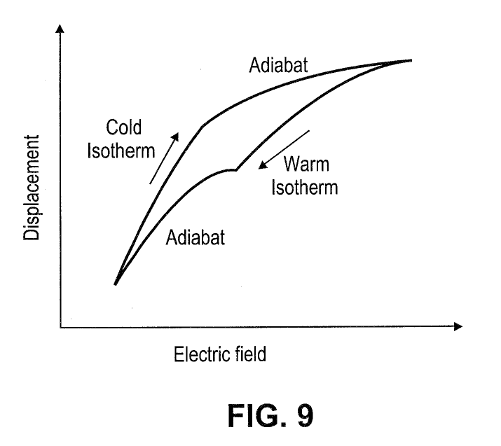

According to various embodiments, there is a method of extracting electrical power in the pyroelectric energy generator 100, 300 using the Carnot cycle 800, shown in FIG. 8. For simplicity, a pyroelectric generator 300 including a single stack of pyroelectric layer 330 disposed between the first thermal switch 340 and the second thermal switch 340′, as shown in FIG. 3 will be used for discussion of the method of extracting electrical power. The Carnot cycle 700 shown in FIG. 8 is in the temperature-entropy plane and in FIG. 9 is in the displacement-electric field plane. The method of extracting electrical power in the pyroelectric energy generator 100 using the Carnot cycle 800 can include the first isothermal step (a) of closing the second liquid crystal thermal switch 340′ adjacent to the second reservoir 315 at the temperature T₂ and opening the first liquid crystal thermal switch 340 adjacent to the first reservoir 310 at a temperature T₁ on the other side to the pyroelectric layer 330 to transfer heat from the second reservoir 315 at T₂ to the pyroelectric layer 330 at a temperature T₃ (T₃<T₂). The isothermal step (a) can also include maintaining the temperature of the pyroelectric layer 330 constant at T₃ by decreasing the applied electric field. The Carnot cycle 800 can also include an adiabatic step (b) of opening both the first and the second liquid crystal thermal switches 340, 340′ and changing the temperature of the pyroelectric layer 330 from T₄ to T₃ by decreasing the applied electric field on the pyroelectric layer 330, wherein T₄<T₁. The Carnot cycle 800 can further include a step (c) of closing the first liquid crystal thermal switch 340 and opening the second liquid crystal thermal switch 340′, such that heat is transferred from the first reservoir 310 at the temperature T₁ to the pyroelectric layer 330 at temperature T₄ (T₄ being less than T₁). The isothermal step (c) can further include keeping the temperature of the pyroelectric layer constant at T₄, by extracting electrical power from the pyroelectric layer 330. The Carnot cycle 800 can also include step (d) of opening both the first and the second liquid crystal thermal switches 340, 340′ to induce a temperature change of the pyroelectric layer from T₄ to T₃ and extracting electrical power from the pyroelectric layer 330. The steps a-d can be repeated as desired, across each stack of alternating pyroelectric layers 130, 330 and liquid crystal thermal switches 140, 340, 340′ of the multilayer stack. Furthermore, by appropriately adjusting the heat flow with thermal switches 140 and the temperature of the pyroelectric layers 130 with applied voltages, each pyroelectric layer 130 can closely approximate the rectangular Carnot heat cycle 700 in the temperature-entropy plane as shown in FIG. 8. This cycle maximizes the electrical power that can be extracted for a given heat flow. Each of the one or more pyroelectric layers 130 in the pyroelectric energy generator 100 can operate in a narrow temperature range. In various embodiments, the composition of each pyroelectric layer 130 can be further adjusted to tune its Curie temperature to further optimize the pyroelectric and electrocaloric effects for its operation.

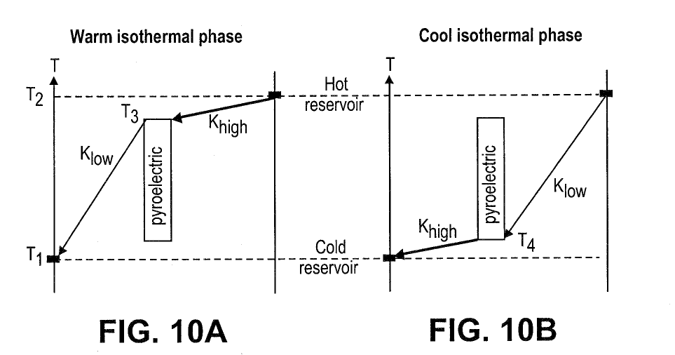

FIGS. 10A and 10B illustrate the heat flow in a single pyroelectric layer 130 during the warm and cool isothermal phases of the Carnot cycle 800 shown in FIG. 8. The relative thickness of the arrow indicates the magnitude of the heat flow through liquid crystal thermal switches 140. In the “closed” state, the liquid crystal thermal switches 140 can have high thermal conductivity K_{high}, and in the open state they can have low thermal conductivity K_{low}. In various embodiments, the ratio K_{high}/K_{low} can be greater that about 3.The larger the ratio, the lower the entropy generating heat leakage through the “open” switches and the greater the efficiency with which the pyroelectric energy generator 100 can generate electrical power.

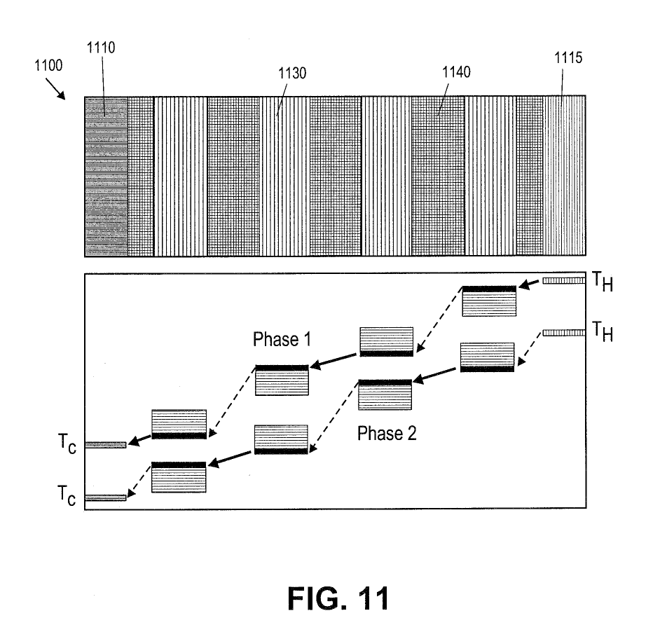

FIG. 11 illustrates operation of an exemplary multilayer pyroelectric energy generator 1100, in accordance with various embodiments of the present teachings. To effectively use a stack of pyroelectric layers 1130 in a heat engine such as, the pyroelectric energy generator 1100, the thermal connections between the pyroelectric layers 1130 has to be opened and closed appropriately as the pyroelectric layers 1130 are heated or cooled. The multilayer pyroelectric energy generator 1100 can operate in a “bucket brigade” mode, rhythmically passing heat between adjacent pyroelectric layers 1130. Thermal switches 1140 on both sides of each of the pyroelectric layers 1130 can control the heat flow. The top panel in FIG. 11 is a schematic of a pyroelectric energy generator 1100 with four pyroelectric layers 1130. The pyroelectric layers 1130 are connected to the hot and cold ends of the device 1100 and to each other by thermal switches 1140. The bottom panel shows the temperature profiles of the pyroelectric energy generator 1100 during two phases of operation. When the thin-film heat engine operates as a pyroelectric energy generator 1100, the heat flow is from the hot reservoir 1115 to the cold reservoir 1110 (to the left) and electrical power is extracted. The sequence of voltage and heat switch changes is similar to that of the electrocaloric cooling device 700 cycle described earlier. The important difference is that in the pyroelectric energy generator 1100, there is a net flow of heat into the pyroelectric material when it is hot and out of this material when it is cool, the reverse of what happens in the electrocaloric cooling device 700.

The pyroelectric generators according to the present teachings can be thin, flat devices that can be attached to a large variety of hot surfaces to salvage electrical power. Furthermore, the materials used in the pyroelectric generators can be relatively inexpensive and the growth techniques are simple and are well established in the prior art. Hence, pyroelectric generators provide a cost effective approach to salvaging electric power from heat that would otherwise be wasted.

According to various embodiments, there is a method of forming a device 100. The method can include providing a first reservoir 110 at a first temperature T₁ and providing a second reservoir 115 at a second temperature T₂, wherein the first temperature T₁ is less than the second temperature T₂. The method can also include forming a multilayer stack of alternating one or more electrocaloric layers 130 and liquid crystal thermal switches 140 between the first reservoir 110 and the second reservoir 115, such that each of the one or more active layers 130 is sandwiched between two liquid crystal thermal switches 140. The method of forming a device 100 can further include providing one or more power supplies 150 to apply voltage to the plurality of liquid crystal thermal switches 140 and the one or more active layers 130.

In some embodiments, the step of forming a multilayer stack of alternating one or more active layers 130 and liquid crystal thermal switches 140 can include forming a first layer 142 of metal, forming a thin layer of liquid crystal over the first layer of metal, forming a second layer 146 of metal over the thin layer 144 of liquid crystal, forming an active layer 130 over the second layer 146 of metal and repeating the above mentioned steps to form the multilayer stack of alternating one or more active layers 130 and liquid crystal thermal switches 140. In some embodiments, the step of forming a thin layer of liquid crystal can further include adding a plurality of carbon nanotubes to the thin layer of liquid crystal. In certain embodiments, the step of forming an active layer 130, 130B over the second layer 146 of metal further include forming a first thin active layer 132 over a first thin electrode layer 134, as shown in FIG. 1B, forming a second thin electrode layer 134 over the first thin active layer 132, and so on to form the active layer 130B including a multilayer stack of alternating thin active layers 132 and electrode layers 134.

In other embodiments, the step of forming a multilayer stack of alternating one or more active layers 130, 230 and liquid crystal thermal switches 140, 240 can include forming a first layer 142, 242 of metal and providing a first insulating layer 221 over the first layer 242 of metal. In various embodiments, the first insulating layer 221 can include one or more pairs of first interdigitated electrodes 248 on a first surface 223 of the first insulating layer 221 on a side opposite the first layer 242 of metal, wherein each of the one or more pairs of first interdigitated electrodes 248 can include a plurality of first electrodes 249. The method can also include forming a thin layer 244 of liquid crystal 245 over the first surface 223 of the first insulating layer 221 and providing a second insulating layer 222 over the thin layer 244 of liquid crystal 245, such that a second surface 225 of the second insulating layer 222 is disposed over the thin layer 244 of liquid crystal 245. In some embodiments, the step of forming a thin layer 144, 244 of liquid crystal can further include adding a plurality of carbon nanotubes to the thin layer 144,244 of liquid crystal 245. In various embodiments, the second insulating layer 222 can include one or more pairs of second interdigitated electrodes 248′ on the second surface 225 of the second insulating layer 222. In various embodiments, each of the one or more pairs of second interdigitated electrodes 248′ can include a plurality of second electrodes 249′ having similar arrangement as that of first electrodes 249 shown in FIG. 2B. The method can further include forming a second layer 246 of metal over the second insulating layer 222 on a side opposite the second surface 222, forming an active layer 130 over the second layer 146, 246 of metal, and repeating the above steps, as desired, to form the multilayer stack 100 of alternating one or more active layers 130 and liquid crystal thermal switches 140, 240, as shown in FIG. 1.

Referring back to the method of forming a device 100, the step of forming one or more multilayer stacks of alternating active layers 130 and liquid crystal thermal switches 140 between the first reservoir 110 and the second reservoir 115 can include forming one or more multilayer stacks of alternating electrocaloric layers 130 and liquid crystal thermal switches 140 between the first reservoir 110 and the second reservoir 115. The device 100, including the electrocaloric layer can be an electrocaloric cooling device.

Referring back to the method of forming a device 100, the step of forming one or more multilayer stacks of alternating active layers 130 and liquid crystal thermal switches 140 between the first reservoir 110 and the second reservoir 115 can include forming one or more multilayer stacks of alternating pyroelectric layers 130 and liquid crystal thermal switches 140 between the first reservoir 110 and the second reservoir 115. The device 100, including the pyroelectric layer can be a pyroelectric energy generator.

While the invention has been illustrated respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A device comprising:
a first reservoir at a first temperature;
a second reservoir at a second temperature, wherein the second temperature is higher than the first temperature;
a plurality of liquid crystal thermal switches disposed between the first reservoir and the second reservoir;
one or more active layers disposed between the first reservoir and the second reservoir, such that each of the one or more active layers is sandwiched between two liquid crystal thermal switches; and
one or more power supplies to apply voltage to the plurality of liquid crystal thermal switches and the one or more the active layers.

2. The device of claim 1, wherein each of the plurality of liquid crystal thermal switches comprises a thin layer of liquid crystal sandwiched between two metal layers.

3. The device of claim 2, wherein the thin layer of liquid crystal comprises carbon nanotubes.

4. The device of claim 1, wherein each of the one or more active layers further comprises a stack of alternating thin active layers and electrode layers, such that each of the thin active layer is disposed between two electrode layers.

5. The device of claim 1, wherein each of the one or more active layers comprises an electrocaloric layer.

6. The device of claim 5, wherein the device is an electrocaloric cooling device.

7. An air conditioning unit comprising the electrocaloric cooling device of claim 6.

8. An electronic device comprising the electrocaloric cooling device of claim 6 for cooling individual electronic components, wherein the individual electronic components comprises the first reservoir.

9. A refrigerator comprising the electrocaloric cooling device of claim 6.

10. The device of claim 1, wherein each of the one or more active layers comprises a pyroelectric layer.

11. The device of claim 10, wherein the device is a pyroelectric energy generator.

12. An automobile comprising the pyroelectric energy generator of claim 10 for extracting electrical energy from a surface that is at a temperature different from its surrounding environment, wherein the surface comprises the second reservoir.

13. The automobile of claim 12, wherein the surface is a radiator.

14. The automobile of claim 12 wherein the surface is an exhaust system.

15. A furnace comprising the pyroelectric energy generator of claim 11 for extracting electrical energy from its surface that is at a temperature different from its surrounding environment, wherein the surface comprises the second reservoir.

16. The pyroelectric energy generator of claim 11, wherein one of the two reservoirs comprises a human body.

17. A method of forming a device comprising:
providing a first reservoir at a first temperature;
providing a second reservoir at a second temperature, wherein the second temperature is higher than the first temperature;
forming one or more multilayer stacks of alternating active layers and liquid crystal thermal switches between the first reservoir and the second reservoir, such that each active layer is sandwiched between two liquid crystal thermal switches; and
providing one or more power supplies to apply voltage to the plurality of liquid crystal thermal switches and the one or more active layers.

18. The method of forming a device according to claim 17 wherein the step of forming a multilayer stack of alternating one or more active layers and liquid crystal thermal switches comprises:
(a) forming a first layer of metal;
(b) forming a thin layer of liquid crystal over the first layer of metal;
(c) forming a second layer of metal over the thin layer of liquid crystal;
(d) forming an active layer over the second layer of metal; and
(e) repeating steps a-d, as desired, to form the multilayer stack of alternating active layers and liquid crystal thermal switches.

19. The method of forming a device according to claim 18 wherein the step of forming an active layer over the second layer of metal further comprises:
a. forming a first thin active layer over the second layer of metal;
b. forming a first thin electrode layer over the first thin active layer;
c. forming a second thin active layer over the first thin electrode layer;
d. forming a second thin electrode layer over the second thin active layer; and
e. repeating steps a-d, as desired, to form the active layer comprising a multilayer stack of alternating thin active layers and electrode layers.

20. The method of forming a device according to claim 17, wherein the step of forming a multilayer stack of alternating one or more active layers and liquid crystal thermal switches comprises:
a. forming a first layer of metal;
b. providing a first insulating layer over the first layer of metal, the first insulaling layer comprising one or more pairs of first interdigitated electrodes on a first surface of the first insulating layer on a side opposite the first layer of metal, wherein each of the one or more pairs of first interdigitated electrodes comprises a plurality of first electrodes;
c. forming a thin layer of liquid crystal over the first surface of the first insulating layer;
d. providing a second insulating layer over the thin layer of liquid crystal, such that a second surface of the second insulating layer is disposed over the thin layer of liquid crystal, the second insulating layer comprising one or more pairs of second interdigitated electrodes on the second surface of the second insulating layer, wherein each of the one or more pairs of second interdigitated electrodes comprises a plurality of second electrodes;
e. forming a second layer of metal over the second insulating layer on a side opposite the second surface;
f. forming an active layer over the second layer of metal; and
g. repeating steps a-f, as desired, to form the multilayer stack of alternating one or more active layers and liquid crystal thermal switches.

21. The method of forming a device according to claim 17, wherein the step of forming a thin layer of liquid crystal further comprises adding a plurality of carbon nanotubes to the thin layer of liquid crystal.

22. The method of forming a device according to claim 17, wherein the step of forming one or more multilayer stacks of alternating active layers and liquid crystal thermal switches between the first reservoir and the second reservoir comprises forming one or more multilayer stacks of alternating electrocaloric layers and liquid crystal thermal switches between the first reservoir and the second reservoir.

23. The method of forming a device according to claim 22, wherein the device is an electrocaloric cooling device.

24. The method of driving heat flow from the first reservoir to the second reservoir in the electrocaloric cooling device of claim 23 comprising the steps of:
(a) closing the second liquid crystal thermal switch adjacent to the second reservoir at a temperature T₂, opening the first liquid crystal thermal switch adjacent to the first reservoir at a temperature T₁ on the other side of the electrocaloric layer thereby transferring heat from the electrocaloric layer at a temperature T₃ to the second reservoir at temperature T₂ and keeping the temperature of the electrocaloric layer constant at T₃ by increasing the electric field across the electrocaloric layer, wherein T₃ is greater than T₂ and T₂ is greater than T₁;
(b) opening both the first and the second liquid crystal thermal switches and changing the temperature of the electrocaloric layer from T₃ to T₄ by decreasing the electric field across the electrocaloric layer, wherein T₄ is less than T₁;
(c) closing the first liquid crystal thermal switch and opening the second liquid crystal thermal switch, to extract heat from the first reservoir at T₁ to the electrocaloric layer at T₄, and keeping the temperature of the electrocaloric layer constant at T₄ decreasing the electric field across the electrocaloric layer;
(d) opening both the first and the second liquid crystal thermal switches and increasing the temperature of the electrocaloric layer from T₄ to T₃ by increasing the electric field across the electrocaloric layer; and
repeating steps a-d, as desired, across each stack of alternating electrocaloric layers and liquid crystal thermal switches of the multilayer stack.

25. The method of forming a device according to claim 17, wherein the step of forming one or more multilayer stacks of alternating active layers and liquid crystal thermal switches between the first reservoir and the second reservoir comprises forming one or more multilayer stacks of alternating pyroelectric layers and liquid crystal thermal switches between the first reservoir and the second reservoir.

26. The method of forming a device according to claim 25, wherein the device is a pyroelectric energy generator.

27. The method of extracting electrical power in the pyroelectric energy generator of claim 26 comprising the steps of:
(a) closing the second liquid crystal thermal switch adjacent to the second reservoir at the temperature T₂ and opening the first liquid crystal thermal switch adjacent to the first reservoir at a temperature T₁ (T₁ <T₂) to transfer heat from the second reservoir at T₂ to the pyroelectric layer at a temperature T₃ (T₃<T₂) and maintaining the temperature of the pyroelectric layer constant at T₃ by decreasing the applied electric field;
(b) opening both the first and the second liquid crystal thermal switches and changing the temperature of the pyroelectric layer from T₄ to T₃ by decreasing the applied electric field on the pyroelectric layer, wherein T₃<T₁;
(c) closing the first liquid crystal thermal switch and opening the second liquid crystal thermal switch, such that heat is transferred from the first reservoir at T₁ to the pyroelectric layer at T₄ (T₄<T₁) and extracting electrical power from the pyroelectric layer by keeping the temperature of the pyroelectric layer constant at T₄;
(d) opening both the first and the second liquid crystal thermal switches to induce a temperature change of the pyroelectric layer from T₄ to T₃ and extracting electrical power from the pyroelectric layer; and
repeating steps a-d, as desired, across each stack of alternating pyroelectric layers and liquid crystal thermal switches of the multilayer stack.
